(19) United States
(12) Patent Application Publication
(10) Pub. No.: US 2013/0271937 A1
(43) Pub. Date: Oct. 17, 2013

(54) ELECTRONIC COMPONENT AND ELECTRONIC APPARATUS

(71) Applicant: KABUSHIKI KAISHA TOSHIBA, Tokyo (JP)

(72) Inventors: Nobuhiro YAMAMOTO, Yokohama (JP); Takahisa FUNAYAMA, Musashino (JP)

(73) Assignee: KABUSHIKI KAISHA TOSHIBA, Tokyo (JP)

(21) Appl. No.: 13/735,246

(22) Filed: Jan. 7, 2013

(30) Foreign Application Priority Data
Apr. 17, 2012 (JP) 2012-093706

(51) Int. Cl. H05K 1/18

(52) U.S. Cl. CPC H05K 1/181
USPC 361/773; 174/255

(57) ABSTRACT

According to one embodiment, an electronic apparatus includes a substrate, a first electronic component, and a reinforcing member. The substrate includes first electrodes. The first electronic component includes a base, second electrodes, and solders configured to connect the first electrodes to the second electrodes. The reinforcing member includes a supporting member between the substrate and the base and a reinforcing material fixed to the supporting member, the reinforcing member fixed to the substrate and the base, and the reinforcing material formed of a thermosetting resin configured to remove an oxide film and fastened to the solders and the substrate.

### CROSS-REFERENCE TO RELATED APPLICATIONS

This application is based upon and claims the benefit of priority from Japanese Patent Application No. 2012-093706, filed Apr. 17, 2012, the entire contents of which are incorporated herein by reference.

### FIELD

Embodiments described herein relate generally to electronic component and electronic apparatus.

### BACKGROUND

A television receiver comprises a substrate comprising various electronic components. Such electronic components are mounted on the substrate with a solder such as a soft solder. When soldering with the solder, an oxide film formed on a surface of an electrode of the substrate is removed by, for example, flux. Furthermore, to reinforce the soldering part between the electronic components and substrate, an underfill resin is used, for example.

In a mounting process of electronic component comprising a solder, there is room for improvement such as reducing steps in the process.

### BRIEF DESCRIPTION OF THE DRAWINGS

A general architecture that implements the various features of the embodiments will now be described with reference to the drawings. The drawings and the associated descriptions are provided to illustrate the embodiments and not to limit the scope of the invention.

FIG. 1 is an exemplary perspective view showing a TV according to a first embodiment;

FIG. 2 is an exemplary perspective view showing a part of a substrate and first electronic component of the first embodiment;

FIG. 3 is an exemplary cross-sectional view showing the substrate, first electronic component and reinforcing member of the first embodiment in a disassembled fashion;

FIG. 4 is an exemplary cross-sectional view showing the substrate and the first electronic component mounted thereon of the first embodiment;

FIG. 5 is an exemplary perspective view showing a part of the substrate and first electronic component according to a second embodiment;

FIG. 6 is an exemplary perspective view showing a part of the substrate, first electronic component and second electronic component according to a third embodiment;

FIG. 7 is an exemplary perspective view showing a part of the substrate and first electronic component according to a fourth embodiment;

FIG. 8 is an exemplary perspective view showing a part of the substrate and first electronic component according to a fifth embodiment;

FIG. 9 is an exemplary cross-sectional view showing a part of the substrate and first electronic component of the fifth embodiment;

FIG. 10 is an exemplary perspective view showing a part of the substrate and first electronic component according to a sixth embodiment;

FIG. 11 is an exemplary cross-sectional view showing a part of the substrate and first electronic component according to a seventh embodiment in a disassembled fashion;

FIG. 12 is an exemplary cross-sectional view showing a part of the substrate and the first electronic component mounted thereon of the seventh embodiment;

FIG. 13 is an exemplary cross-sectional view showing a part of the substrate and first electronic component according to an eighth embodiment;

FIG. 14 is an exemplary perspective view showing a portable computer according to a ninth embodiment;

FIG. 15 is an exemplary cross-sectional view showing a part of the substrate and first electronic component according to a tenth embodiment in a disassembled fashion; and

FIG. 16 is an exemplary cross-sectional view showing a part of the substrate and the first electronic components mounted thereon of the tenth embodiment.

### DETAILED DESCRIPTION

Various embodiments will be described hereinafter with reference to the accompanying drawings.

In general, according to one embodiment, an electronic apparatus includes a substrate, a first electronic component, and a reinforcing member. The substrate includes a plurality of first electrodes. The first electronic component includes a base, a plurality of second electrodes on the base, and a plurality of first solders configured to electrically connect the first electrodes to the second electrodes. The reinforcing member includes a supporting member at least partially interposed between the substrate and the base of the first electronic component and a reinforcing material fixed to the supporting member, the reinforcing member fixed to the substrate and the base, and the reinforcing material formed of a first thermosetting resin configured to remove an oxide film and fastened to the first solders and the substrate.

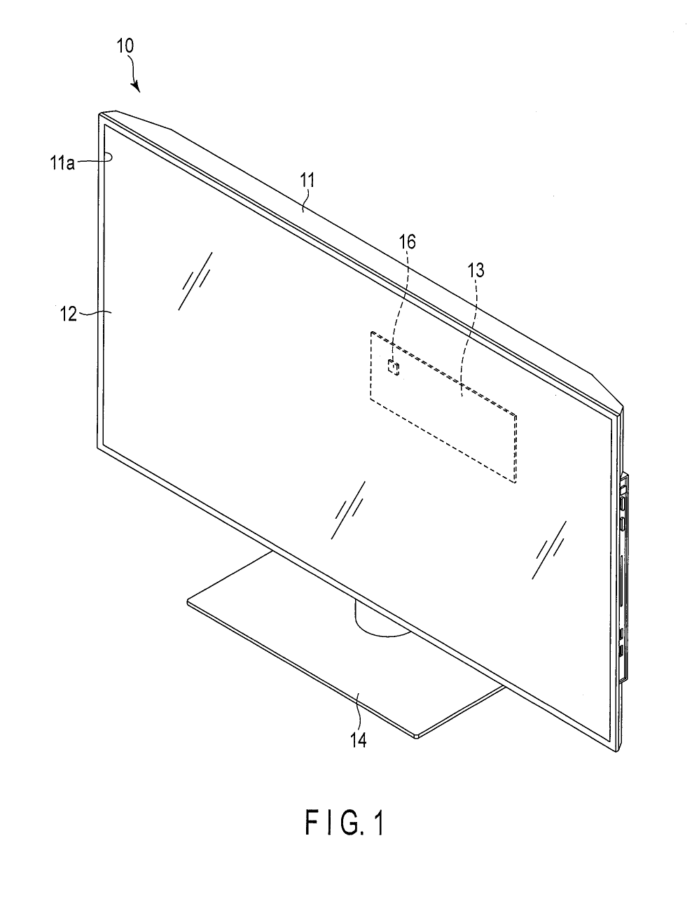

Hereinafter, a first embodiment is described referring to FIGS. 1 to 4. In this specification, it is defined that a before side (that is, a user side) is referred to as a front direction, a far side of the user side is referred to as a rear direction, a left side of the user side is referred to as a left direction, a right side of the user side is referred to as a right direction, an upward side of the user side is referred to as an upper direction, and a lower side of the user side is referred to as a lower direction. When a single element can be referred to by a plurality of names, such names may be added thereto. However, it does not mean that a single element which is referred to by a single name is limited to the single name, or the additional names are limited thereto.

FIG. 1 shows an exemplary television receiver (hereinafter referred to as a TV) 10 according to the first embodiment. The TV 10 is an example of electronic apparatus. As shown in FIG. 1, the TV 10 comprises a casing 11, a display part 12, a substrate 13, and a stand 14.

The casing 11 is formed in a flat box shape. The casing 11 stores the display part 12 and the substrate 13. A display opening 11a is provided in front of the casing 11. The display part 12 is exposed from the display opening 11a.

The display part 12 is, for example, a liquid crystal display (LCD); however, it is not limited to the LCD and may be other image display modules such as a plasma display and an organic electroluminescent display, etc. The display part 12 displays an image on a screen exposed from the display opening 11a of the casing 11. Here, in this specification, the term “image” includes a still picture and a moving picture.

At the rear surface of the casing 11, a stand 14 is attached. The stand 14 supports the casing 11 at a predetermined height. The casing 11 supported by the stand 14 is rotatable within predetermined angles.

The substrate 13 is, for example, a rigid printed wiring board. The substrate is not limited thereto, and various substrates such as a flexible printed wiring board may be applied. The substrate 13 is connected to, for example, the display part 12 through a cable, etc.

As shown by a broken line in FIG. 1, a first electronic component 16 is mounted on the substrate 13. The first electronic component 16 is, for example, a ball grid array (BGA). Furthermore, various components such as condenser, connector, and tuner may be mounted on the substrate 13.

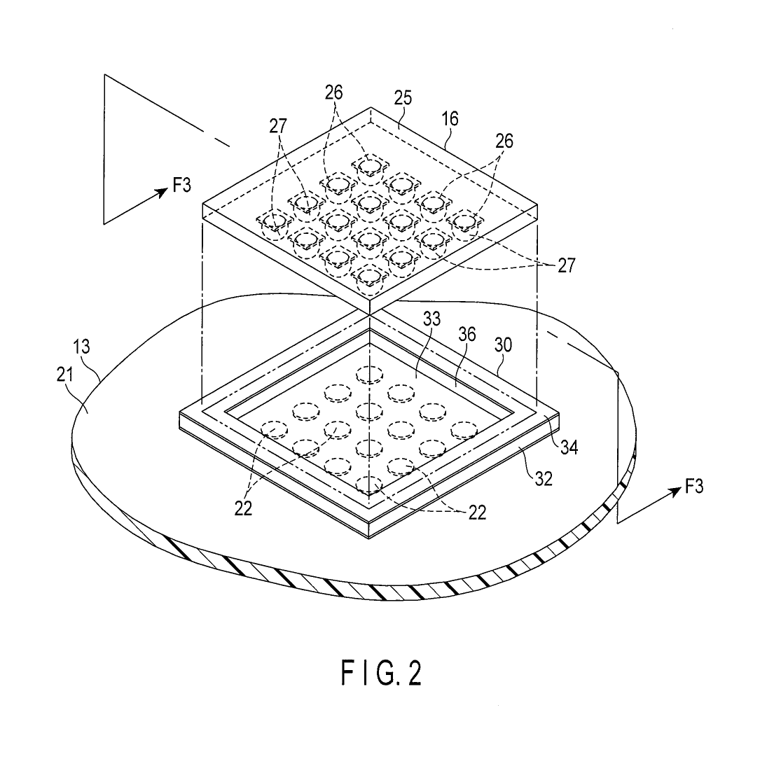

FIG. 2 is an exemplary perspective view showing a part of the substrate 13 and the first component 16. As shown in FIG. 2, the substrate 13 comprises a mounted surface 21 on which the first electronic component 16 is mounted. Various components are mounted and wiring patterns are formed on the mounted surface 21.

As shown by a broken line in FIG. 2, a plurality of first electrodes 22 are provided on the mounted surface 21 of the substrate 13. The first electrodes 22 may be represented by pads, lands, conductive parts, and terminals, for example. The first electrodes 22 are arranged in a matrix, for example. The first electrodes 22 are connected to wiring patterns provided upon the substrate 13, for example.

The first electronic component 16 comprises a base 25, a plurality of second electrodes 26 and a plurality of first solder balls 27. The second electrodes 26 are an example of a plurality of electrodes provided on a base. The first solder balls 27 are an example of first solders. Here, the solders are not limited thereto, and soldering bumps and soldering pastes may be applied.

The base 25 is a rectangular substrate covered by mold resin, for example. As shown by a broken line in FIG. 2, the second electrodes 26 are provided on a bottom surface of the base 25. The second electrodes 26 may be represented by, for example, conductive parts and terminals. The second electrodes 26 correspond to the first electrodes 22 and arranged in a matrix, for example.

As shown by a broken line in FIG. 2, the first solder balls 27 are connected to the second electrodes 26, respectively. The diameter of the first soldering ball 27 is between 500 and 1000 pm, for example. The first soldering ball is melted at 220° C., for example. The first soldering ball 27 may be represented by, for example, terminals, connecting parts, joining parts and joining materials.

A reinforcing member 30 is attached to the substrate 13. The reinforcing member 30 may be represented by, for example. an attachment, supporting part, fixing part, and implementation part. The reinforcing member 30 is located at a position where the first electrodes 22 are provided.

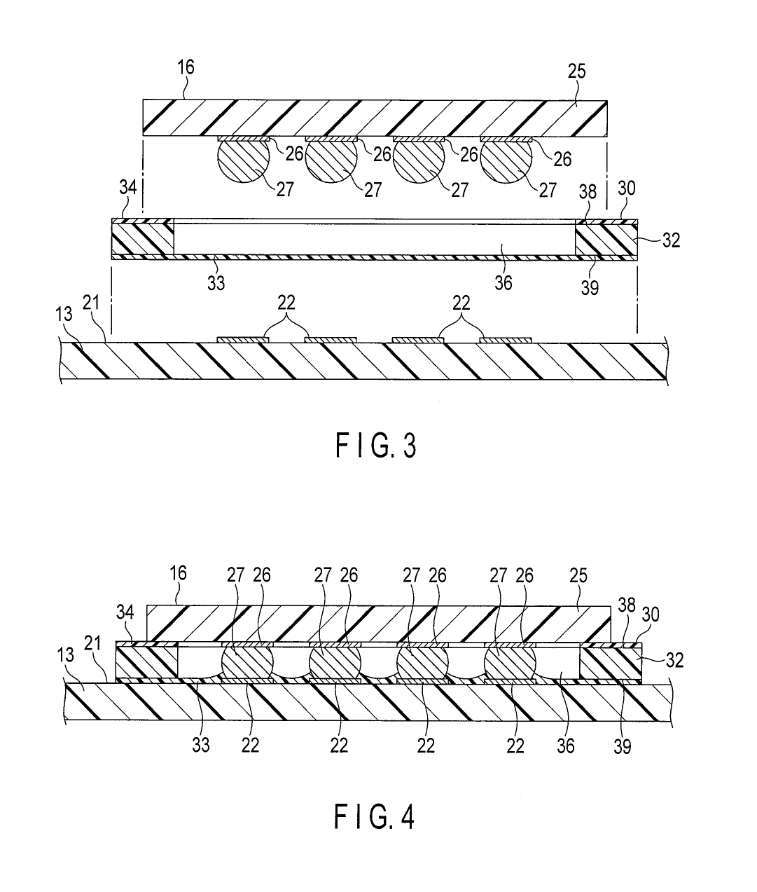

FIG. 3 is an exemplary cross-sectional view showing the substrate 13, the first electronic component 16 and reinforcing member 30 in a disassembled fashion, along line F3-F3 in FIG. 2. As shown in FIG. 3, the reinforcing member 30 comprises a supporting member 32, a reinforcing material 33 and a fixing material 34. The fixing material 34 is an example of thermosetting resin.

As shown in FIG. 2, the supporting member 32 is formed of, for example, epoxy resin in a rectangular frame shape. Here, the supporting member 32 may be formed of other materials such as acryl resin and polyimide resin.

The supporting member 32 comprises a first opening 36. The first opening 36 are holes configured to surround the first electrodes 22. In other words, the size of the first opening 36 is larger than a region where the first electrodes 22 are arranged. The first opening 36 is further configured to surround the second electrodes 26. The size of the first opening 36 is smaller than the base 25 of the first electronic component 16.

As shown in FIG. 3, the supporting member 32 comprises a first surface 38 and a second surface 39. The first surface 38 may be represented by an upper surface, top surface, and surface in the electronic component-side, for example. The second surface 39 may be represented by a lower surface, bottom surface, and surface in the substrate-side. At least a part of the first surface 38 faces the base 25 of the first electronic component 16. In other words, the first surface 38 overlaps with the base 25. The second surface 39 positions opposite to the first surface 38. The second surface 39 faces the mounted surface 21 of the substrate 13.

The reinforcing material 33 is attached to the second surface 39 of the supporting member 32. The reinforcing material 33 is a film formed of, for example, thermosetting resin configured to remove an oxide film. The reinforcing material 33 may be represented by, for example, a sheet material, reinforcing resin, and oxide film remover. The thickness of the reinforcing material 33 is, for example, 100 μm or less. The reinforcing material 33 comprises an activator, for example, and is configured to remove an oxide film generated on metal when being heated.

The reinforcing material 33 is thermoplastic before it is in a thermosetting condition. The reinforcing material 33 is liquefied when it is heated up to 150° C. That is, the reinforcing material 33 liquefies at the temperature lower than that of the first solder balls 27 starting to melt. Here, the temperature is not limited to the condition above, and it is acceptable that the reinforcing material 33 liquefies at the temperature higher than that of the first solder balls 27 starting to melt. The liquefied reinforcing material 33 returns to the state before liquefaction when it is cooled. The reinforcing material 33 starts to be thermally-cured when it is heated up to, for example, 200° C. The reinforcing material 33 is, for example, added to a supporting member 32 in a liquefied state and attached to the supporting member 32 when it is cooled down before thermally-curing.

The reinforcing material 33 is provided over the region surrounded by the supporting member 32. In other words, the first opening 36 of the supporting member 32 is blocked by the reinforcing material 33. Here, the reinforcing material may cover only a part of the first opening 36.

The fixing material 34 is attached to the first surface 38 of the supporting member 32. The fixing material 34 is a film formed of, for example, thermosetting resin. Here, as the reinforcing material 33, the fixing material 34 may be a film formed of thermosetting resin configured to remove an oxide film. Furthermore, the fixing material is not limited to the thermosetting resin, and may be other materials such as an adhesive agent which is hardened by other factors such as drying, ultraviolet, and time lapse. The thickness of the fixing material 34 is, for example, 100 μm or less.

The fixing material 34 comprises thermoplastic and thermosetting characteristics as the reinforcing material 33. That is, the fixing material 34 liquefies at the same temperature as that of the reinforcing material 33 and starts to be thermally-cured at the same temperature as that of the reinforcing material 33. The fixing material 34 is, for example, added to a supporting member 32 in a liquefied state and attached to the supporting member 32 when it is cooled down before thermally-curing.

The fixing material 34 is provided only on the first surface 38 of the supporting member 32. In other words, the fixing material 34 forms a hole through the first opening 36 of the supporting member 32. Here, the fixing material 34 may be formed of a plurality of rectangular thermosetting resin films, for example.

FIG. 4 is an exemplary cross-sectional view of the substrate 13 and the first electronic component 16 mounted thereon. The first electronic component 16 is mounted on the substrate 13 as follows.

Firstly, as shown in FIG. 3, a reinforcing member 30 is attached to the substrate 13. More specifically, the reinforcing member 30 is initially placed on the mounted surface 21 of the substrate 13 so that the supporting member 32 surrounds the first electrodes 22. Thereby, the reinforcing material 33 contacts the mounted surface 21 and covers the first electrodes 22. Here, the reinforcing material 33 may be heated and cooled at this point to be attached to the substrate 13. Therefore, as shown in FIG. 2, the reinforcing member 30 is fixed to the substrate 13.

Then, the first electronic component 16 is placed on the reinforcing member 30 on the substrate 13. Thereby, the first solder balls 27 are placed on the first electrodes 22 by means of the reinforcing material 33. In other words, the reinforcing material 33 interferes between the first solder balls 27 and the first electrodes 22. Furthermore, at least a part of the supporting member 32 is interposed between the base 25 of the first electronic component 16 and the substrate 13.

Next, the first electronic component 16 is pressed against the substrate 13 while being heated. The substrate 13 and the reinforcing member 30 are heated and the reinforcing material 33 and fixing material 34 are liquefied. Thereby, the reinforcing material 33 is pushed out from the interval between the first solder balls 27 and the first electrodes 22, and the first solder balls 27 contact the first electrodes 22. At the same time, the reinforcing material 33 removes an oxide film generated on the first electrodes 22.

When the first electronic component 16 is further heated, the first solder balls 27 are melted. The melted first solder balls 27 are adhered to the first electrodes 22. Thereby, the first electrodes 22 are soldered to the second electrodes 26. In other words, the first solder balls 27 electronically connect the first electrodes 22 to the second electrodes 26.

As shown in FIG. 4, the liquefied reinforcing material 33 is attached to the mounted surface 21 of the substrate 13, the first electrodes 22, and the first solder balls 27. When the first solder balls 27 are heated up to the melting temperature, the reinforcing material 33 and the fixing material 34 start to be thermally-cured. When thermally-curing of the reinforcing material 33 is completed, the reinforcing material 33 is fastened to the mounted surface 21, the first electrodes 22, and the first solder balls 27. Thereby, the second surface 39 of the supporting member 32 is fixed to the substrate 13 by means of the reinforcing material 33.

Furthermore, when the first electronic component 16 is pressed against the substrate 13, the base 25 of the first electronic component 16 contacts the fixing material 34. The liquefied fixing material 34 starts to be thermally-cured in a state of adhering to the base 25. Thereby, the supporting member 32 is fixed to the base 25 of the first electronic component 16 by means of the fixing material 34.

When the first electronic component 16 is cooled down, the melted first solder balls 27 go solid.

Thereby, the mounting of the first electronic component 16 is completed.

In the TV 10 having the above-mentioned structure, the thermally-cured reinforcing material 33 is fastened to the substrate 13 and the first solder balls 27. Thereby, contacting portions of the first solder balls 27 and the first electrodes 22 are reinforced and the contacting portions are protected from damage.

Furthermore, the reinforcing material 33 removes the oxide film on the first electrodes 22 when the first electronic component 16 is mounted on the substrate 13. The reinforcing material 33 removes the oxide film and is pushed out due to liquefaction, and thus, the first solder balls 27 are electrically connected to the first electrodes 22.

As above, the reinforcing material 33 removes the oxide film on the first electrodes 22 and is fastened to the first solder balls 27 and the substrate 13. Thus, a conventional process of removing an oxide film such as supplying flux and a conventional process of reinforcement such as supplying underfill can be performed at the same time, and thereby, the production cost of the TV 10 can be reduced.

Furthermore, the supporting member 32 is fixed to the substrate 13 by the reinforcing material 33, and is fixed to the base 25 of the first electronic component 16 by means of the fixing material 34. Since the first electronic component 16 is fixed to the substrate 13 via the supporting member 32, the contacting portions of the first solder balls 27 and the first electrodes 22 can be reinforced more rigidly. Thereby, the contacting portions of the first electrodes 22 and the first solder balls 27 are rigidly reinforced.

Since the reinforcing material 33 is attached to the supporting member 32, arrangement of the reinforcing material 33 is easily carried out even when it is very thin. Furthermore, since the reinforcing material 33 is arranged to cover the first opening 36, arrangement of the reinforcing material 33 is further simplified. That is, a possibility that the reinforcing material 33 would be torn apart or crinkled can be suppressed and thereby, the production cost of the TV 10 is reduced.

Furthermore, the supporting member 32 is fixed to the substrate 13 and the base 25 of the first electronic component 16 by means of the thermosetting reins of fixing material 34 and reinforcing material 33. Thereby, the first electronic component 16 and the reinforcing member 30 can be attached in a single heat treatment, and the production cost of the TV 10 is reduced.

Since the reinforcing material 33 in a pre-thermally-curing state is liquefied and has a thermoplastic characteristic, the reinforcing material 33 is easily attached to the supporting member 32 and the substrate 13. Even when the reinforcing material 33 is melted by heating and attached to the supporting member 32 and the substrate 13, the reinforcing material 33 keeps its original form.

Furthermore, the liquefaction temperature of the reinforcing material 33 is lower than the melting temperature of the first solder balls 27. Thereby, an oxide film is removed before the melt of the first solder balls 27, and soldering is performed in a stabled condition. Furthermore, if the first solder balls 27 melt in different timing, the first electronic component 16 may be inclined, but the structure above will suppress such an inclination problem. Furthermore, the melted first solder balls 27 are prevented from flowing out to the liquefied reinforcing material 33. Here, even when the liquefaction temperature of the reinforcing material 33 is higher than the melting temperature of the first solder balls 27, the first solder balls 27 do not flow out easily because of the surface tension thereof.

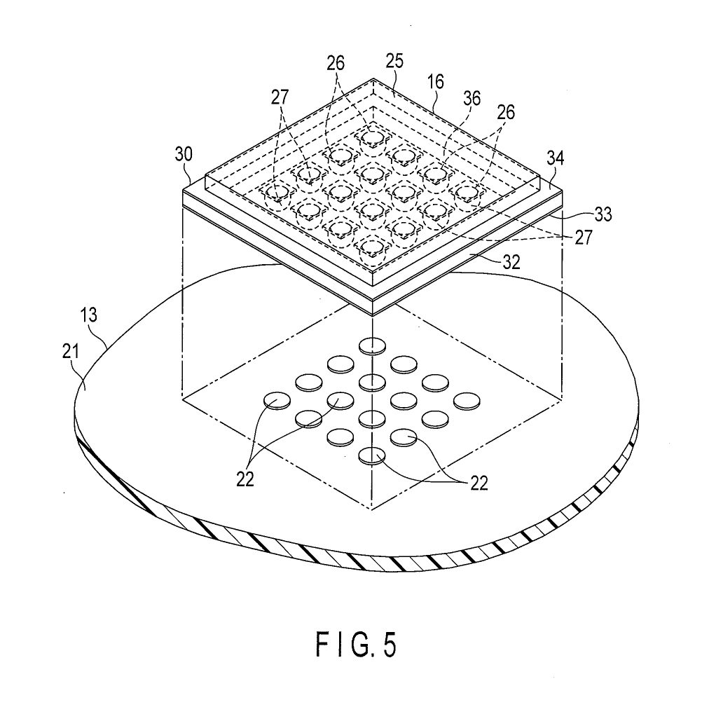

Hereinafter, referring to FIG. 5, the second embodiment is described. Here, in at least one embodiment disclosed below, the same reference numbers are applied to elements having the same function as that of the TV 10 in the first embodiment. Furthermore, a part of or the entire explanation of such elements may be omitted.

FIG. 5 is an exemplary perspective view showing a part of the substrate 13 of the second embodiment. As shown in FIG. 5, the first electronic component 16 mounted on the substrate 13 comprises the reinforcing member 30. In other words, the first electronic component 16 is mounted on the substrate 13 with the reinforcing member 30 preliminarily mounted thereon.

At least a part of the first surface 38 of the supporting member 32 is attached to the base 25 of the first electronic component 16 by the fixing material 34. The supporting member 32 is fixed to the base 25 with the fixing material 34 thermally-cured during the mounting.

The reinforcing material 33 is attached to the second surface 39 of the supporting member 32. The reinforcing material 33 blocks the first opening 36 to cover the first solder balls 27. The reinforcing material 33 is attached to each of the first solder balls 27.

During the mounting, the first electronic component 16 is placed on the substrate 13 and thus, the reinforcing material 33 is interposed between the first solder balls 27 and the first electrodes 22. Furthermore, the reinforcing material 33 covers the first electrodes 22.

When the first electronic component 16 is heated, the reinforcing material 33 liquefies and attaches to the first electrodes 22 and the mounted surface 21 of the substrate 13. The thermally-cured reinforcing material 33 reinforces the contacting parts of the first electrodes 22 and the first solder balls 27 as in the first embodiment. Furthermore, the reinforcing material 33 fixes the supporting member 32 to the substrate 13.

In the TV 10 with the above-mentioned structure, the supporting member 32 to which the reinforcing material 33 covering the first solder balls 27 is attached is preliminarily affixed to the first electronic component 16. Thereby, the first electronic component 16 is easily mounted on the substrate 13.

The reinforcing material 33 is attached to the second surface 39 of the supporting member 32. The second surface 39 and the tips of the first solder balls 27 are positioned on approximately the same flat surface. Thereby, the reinforcing material 33 is easily attached to the second surface 39 and the first solder balls 27.

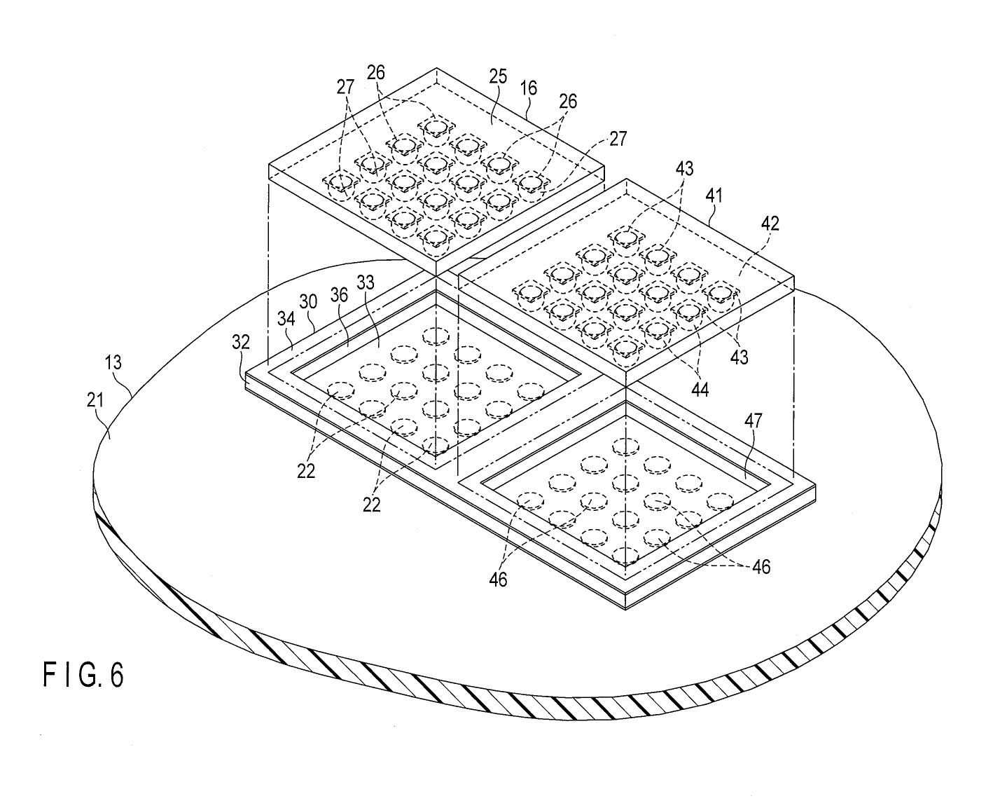

Next, the third embodiment is explained referring to FIG. 6. FIG. 6 is an exemplary perspective view showing a part of the substrate 13, the first electronic component 16, and second electronic component 41 according to the third embodiment. As shown in FIG. 6, the second electronic component 41 is mounted on the substrate 13.

The second electronic component 41 is, for example, BGA. The second electronic component 41 comprises a bottom part 42, a plurality of third electrodes 43 and second solder balls 44. The second solder balls 44 are an example of second solders. Here, the second solders are not limited thereto, and, for example, solder bumps and solder pastes may be applied.

The bottom part 42 opposes to the mounted surface 21 of the substrate 13. The third electrodes 43 are provided on the bottom part 42. The third electrodes 43 may be denoted such as conductive parts and terminals. The third electrodes 43 are arranged in a matrix, for example.

The second solder balls 44 are connected to the third electrodes 43, respectively. The diameter and melting temperature of the second solder balls 44 are the same as those of the first solder balls 27. Here, the diameter and melting temperature of the second solder balls 44 may be different from those of the first solder balls 27. The second solder balls 44 may be denoted such as terminals, connecting parts, contacting parts and contacting materials.

A plurality of fourth electrodes 46 are provided on the mounted surface 21 of the substrate 13. The fourth electrodes 46 correspond to the third electrodes 43 of the second electronic component 41, and are arranged in a matrix, for example. The fourth electrodes 46 are connected to the wiring patterns formed on the substrate 13.

The supporting member 32 of the reinforcing member 30 further comprises a second opening 47 in addition to the first opening 36. The second opening 47 is a hole configured to surround the third electrodes 43 and fourth electrodes 46. In other words, the size of the second opening 47 is larger than the region where the fourth electrodes 46 are arranged. The size of the second opening 47 is smaller than the size of the bottom part 42 of the second electronic component 41.

The reinforcing material 33 covers both the first opening 36 and second opening 47. That is, a single reinforcing material 33 are provided over the first opening 36 and the second opening 47. Here, the reinforcing material 33 may be divided to cover the first opening 36 and the second opening 47, separately.

The fixing material 34 is attached to the first surface 38 of the supporting member 32 around the second opening 47. Here, the fixing material 34 may be divided to attach around the first opening 36 and the second opening 47, separately.

The second electronic component 41 is mounted on the substrate 13 similarly to the first electronic component 16. More specifically, the reinforcing member 30 is initially placed on the mounted surface 21 of the substrate 13 so that the supporting member 32 surrounds the first electrodes 22 and the fourth electrodes 46. Then, the second electronic component 41 is placed on the reinforcing member 30 attached to the substrate 13. Thereby, at least a part of the supporting member 32 is interposed between the bottom part 42 of the second electronic component 41 and the substrate 13.

Next, the second electronic component 41 is pressed against the substrate 13 while being heated. The substrate 13 and the reinforcing member 30 are heated and the reinforcing material 33 and fixing material 34 are liquefied. Thereby, the reinforcing material 33 is pushed out from the interval between the second solder balls 44 and the fourth electrodes 46, and the second solder balls 44 contact the fourth electrodes 46. At the same time, the reinforcing material 33 removes an oxide film generated on the fourth electrodes 46.

When the first electronic component 16 is further heated, the second solder balls 44 are melted. The melted second solder balls 44 are adhered to the fourth electrodes 46. Thereby, the fourth electrodes 46 are soldered to the third electrodes 43. In other words, the second solder balls 44 electronically connect the third electrodes 43 to the fourth electrodes 46.

The liquefied reinforcing material 33 is attached to the substrate 13, the fourth electrodes 46, and the second solder balls 44. When the second solder balls 44 are heated up to the melting temperature, the reinforcing material 33 and the fixing material 34 start to be thermally-cured. When thermally-curing of the reinforcing material 33 is completed, the reinforcing material 33 is fastened to the substrate 13, the fourth electrodes 46, and the second solder balls 44.

Furthermore, when the second electronic component 41 is pressed against the substrate 13, the base 42 of the second electronic component 41 contacts the fixing material 34. The liquefied fixing material 34 starts to be thermally-cured in a state of adhering to the base 42. Thereby, the supporting member 32 is fixed to the base 42 of the second electronic component 41 by means of the fixing material 34.

When the second electronic component 41 is cooled down, the melted second solder balls 44 go solid. Thereby, the mounting of the second electronic component 41 is completed. The mounting of the second electronic component 41 is carried out at the same time of the mounting of the first electronic component 16. Here, the mounting of the second electronic component 41 and the mounting of the first electronic component 16 may be carried out separately.

In the TV 10 having the above-mentioned structure, a single reinforcing member 30 reinforces the first electronic component 16 and the second electronic component 41. That is, the electronic components 16 and 41 are mounted at the same time, and thus, the production cost of the TV 10 is reduced.

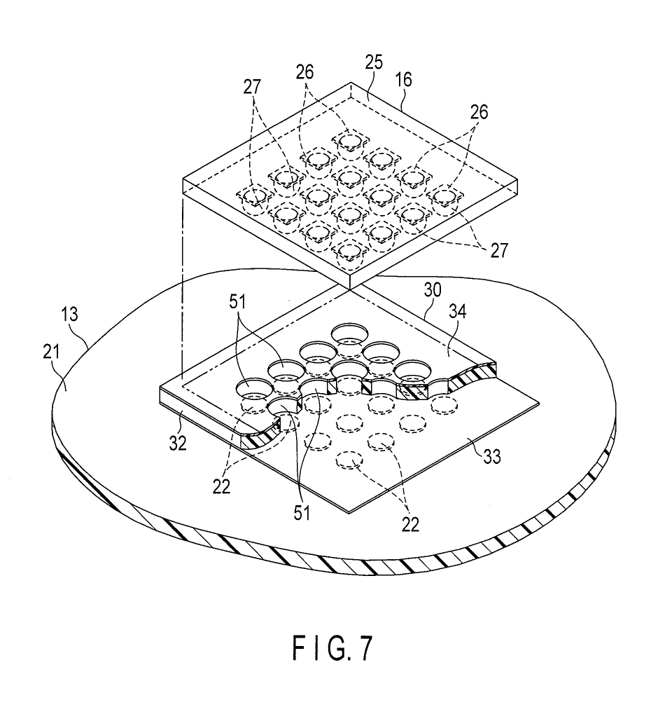

Next, the fourth embodiment is explained referring to FIG. 7. FIG. 7 is an exemplary perspective view showing a part of the substrate 13, and the first electronic component 16 according to the fourth embodiment. In FIG. 7, a part of the supporting member 32 is notched. As shown in FIG. 7, the supporting member 32 of the fourth embodiment is formed in a rectangular plate-like shape.

The supporting member 32 comprises a plurality of openings 51. The openings 51 are provided from the first surface 38 to the second surface 39 of the supporting member 32. The openings 51 correspond to the second electrodes 26 and are arranged in a matrix, for example. The number of openings 51 is equal to that of the second electrodes 26. Here, the number of openings 51 may be less or more than that of the second electrodes 26.

The openings 51 store the first solder balls 27, respectively. In other words, the size of the openings 51 is larger than that of first solder balls 27. Here, one of the openings 51 may store a plurality of first solder balls 27.

The openings 51 are covered by the reinforcing material 33 while the fixing material 34 releases the openings 51. Thereby, the first solder balls 27 can enter the openings 51.

In the TV 10 having the above-mentioned structure, the supporting member 32 comprising the openings 51 is interposed between the substrate 13 and the base 25 of the first electronic component 16. Thereby, a contacting area of the supporting member 32 and the base 25 is larger than that of the first embodiment. Thereby, the reinforcing member 30 can reinforce the contacting parts of the first electrodes 22 and the first solder balls 27 more firmly.

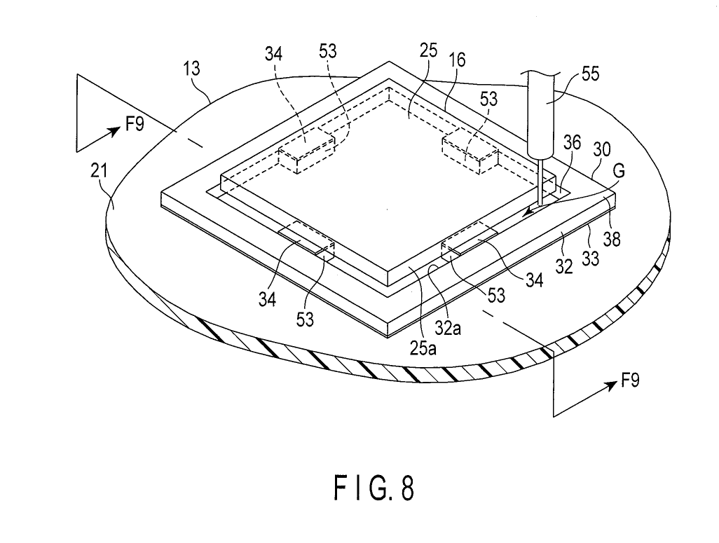

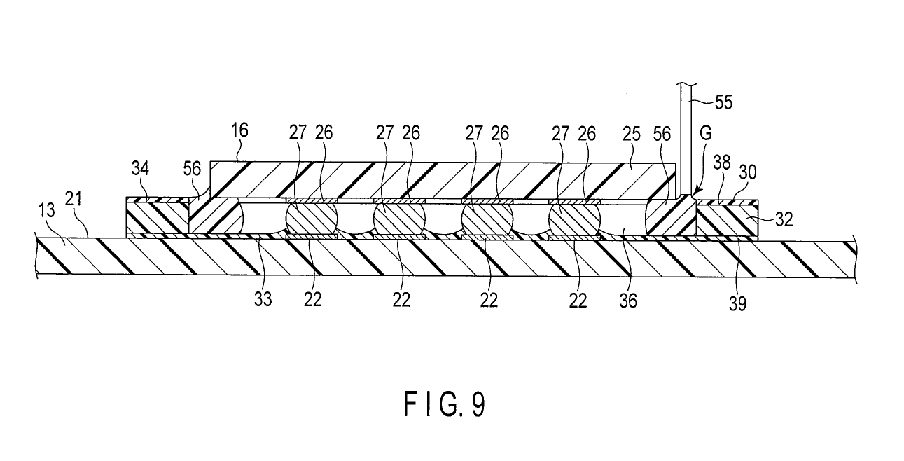

Next, the fifth embodiment is explained referring to FIGS. 8 and 9. FIG. 8 is an exemplary perspective view showing a part of the substrate 13, and the first electronic component 16 according to the fifth embodiment. FIG. 9 is an exemplary cross-sectional view showing a part of the substrate 13 and the first electronic component 16, along line F9-F9 in FIG. 8.

As shown in FIG. 8, the size of the first opening 36 of the fifth embodiment is larger than that of the base 25 of the first electronic component 16. Thereby, a gap G is formed between the inner periphery 32a of the supporting member 32 and the outer periphery 25a of the base 25.

The supporting member 32 comprises a plurality of extending parts 53. The extending parts 53 extend from the inner periphery 32a of the supporting member 32. The extending parts 53 which are a portion of the supporting member 32 are interposed between the substrate 13 and the base 25 of the first electronic component 16. In other words, the extending parts 53 support the base 25.

A plurality of fixing materials 34 are attached to the extending parts 53. The extending parts 53 are fixed to the base 25 of the first electronic component 16 by the thermally-cured fixing materials 34. Here, a single fixing material 34 may be attached to the entire surface of the first surface 38 of the supporting member 32.

In the fifth embodiment, the first electronic component 16 is mounted on the substrate 13 as in the first embodiment. After the first electronic component 16 is mounted on the substrate 13, the contacting parts of the first solder balls 27 and the first electrodes 22 is further reinforced as described below.

Initially, a tip of a dispenser 55 is placed in the gap G. As shown in FIG. 9, the dispenser 55 supplies reinforcing resin 56 between the substrate 13 and the base 25 of the first electronic component 16 from the gap G. The reinforcing resin 56 is thermosetting underfill resin.

The reinforcing resin 56 supplied by the dispenser 56 is adhered to the base 25 of the first electronic component 16 and reinforcing material 33 fixed on the substrate 13. Furthermore, the reinforcing resin 56 is attached to the supporting member 32.

The supplied reinforcing resin 56 is thermally-cured by heating. Thereby, the reinforcing resin 56 is fastened to the base 25 of the first electronic component 16, and further fastened the substrate 13 via the reinforcing material 33. Furthermore, the reinforcing resin 56 is fastened to the supporting member 32.

In the TV 10 having the above-mentioned structure, the thermosetting reinforcing resin 56 is fastened to the base 25 of the first electronic component 16 and the substrate 13. Thereby, the contacting parts of the first electrodes 22 and the first solder balls 27 are reinforced more firmly.

The gap G is formed between the inner periphery 32a of the supporting member 32 and the outer periphery 25a of the base 25. Thereby, even after the first electronic component 16 is mounted on the substrate 13, the reinforcing resin 56 can be supplied by the dispenser 55 through the gap G.

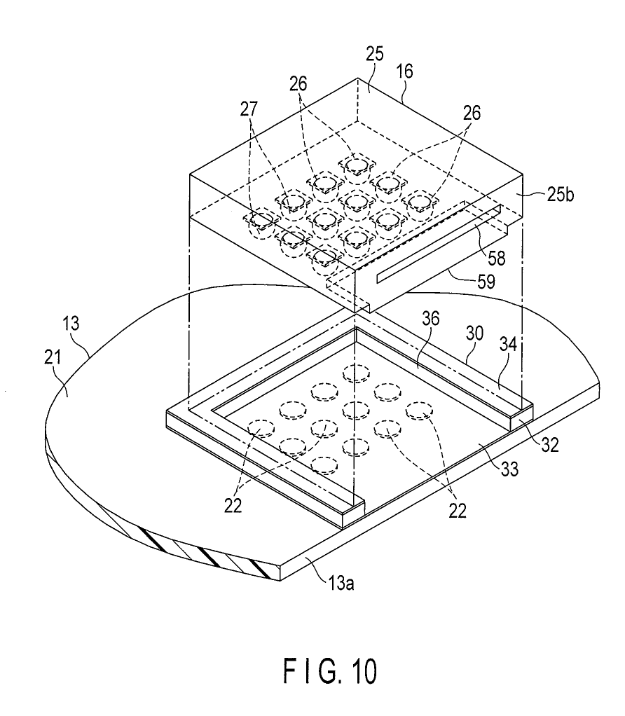

Next, the sixth embodiment is explained referring to FIG. 10. FIG. 10 is an exemplary perspective view showing a part of the substrate 13 and the first electronic component 16 according to the sixth embodiment. As shown in FIG. 10, the first electrodes 22 are arranged near to the periphery 13a of the substrate 13.

The first electronic component 16 of the sixth embodiment is a connector, for example. An insertion port 58 is provided at a side surface 25b of the base 25 of the first electronic component 16. The insertion port 58 is a slit through which a cable terminal, for example, is inserted.

The base 25 of the first electronic component 16 comprises a projection 59. The projection 59 is an example of a projecting part toward the substrate. The projection 59 may be denoted such as projection part and protrusion part. The projection 59 is provided along the side surface 25b of the base 25 and project toward the substrate 13.

The reinforcing member 30 is arranged to contact the periphery 13a of the substrate 13. The supporting member 32 of the reinforcing member 30 is formed in a frame shape opening toward the periphery 13a of the substrate 13. In other words, the supporting member 32 is U-shaped.

As shown in FIG. 10, the first electronic component 16 is mounted on the substrate 13 so that the side surface 25b of the base 25 is arranged along the periphery 13a of the substrate 13. Thereby, the projection 59 of the first electronic component 16 fits the opened part of the supporting member 32 and does not interfere with the supporting member 32. That is, the supporting member 32 is formed in a frame-like shape whose part is opened to release the projection 59.

In the TV 10 having the above-mentioned structure, the supporting member 32 is formed in a frame-like shape whose part is opened to release the projection 59 of the first electronic component 16 and which supports the base 25. Thus, the reinforcing member 30 reinforces the contacting parts of the first electrodes 22 and the first solder balls 27 of the multi-shaped first electronic component 16.

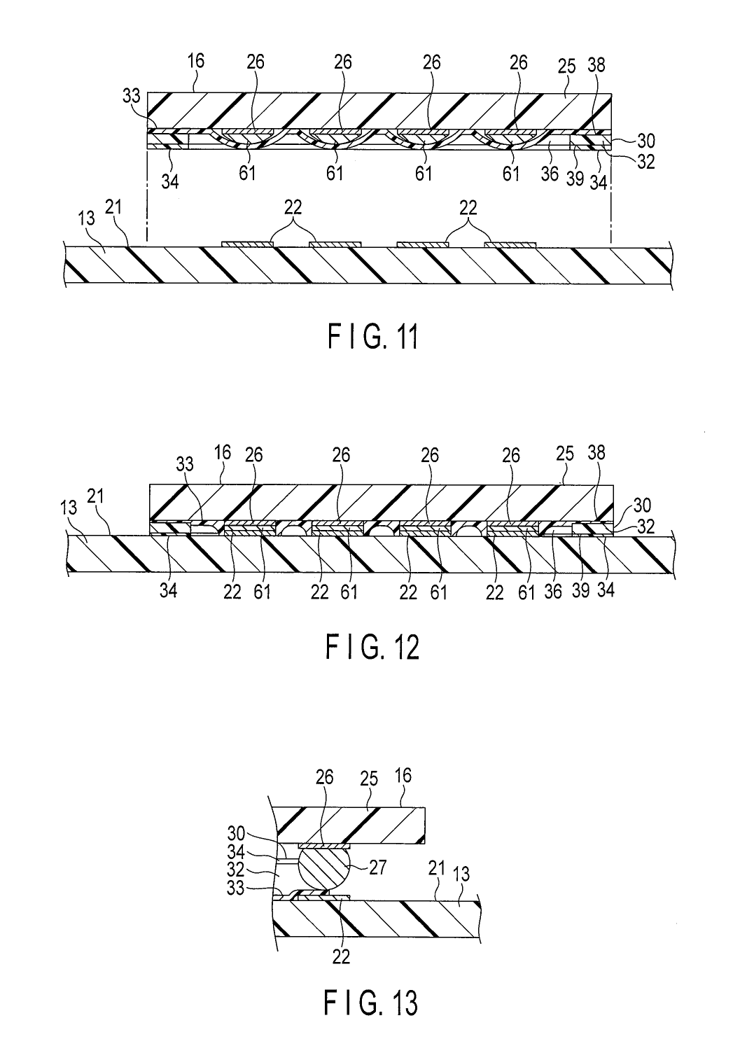

Next, the seventh embodiment is explained referring to FIGS. 11 and 12. FIG. 11 is an exemplary cross-sectional view showing a part of the substrate 13 and the first electronic component 16 according to the seventh embodiment in a disassembled fashion. FIG. 12 is an exemplary cross-sectional view showing a part of the substrate 13 and the first electronic component 16.

The first electronic component 16 of the seventh embodiment is, for example, a flip chip. As shown in FIG. 11, solder bumps 61 are provided with the second electrodes 26 instead of the first solder balls 27 of the first embodiment. The solder bumps 61 may be denoted such as terminals, connecting parts, contacting parts and contacting materials.

Each of the solder bumps 61 projects from the second electrodes 26 in an arcuate shape. Here, the solder bump 61 may project in a trapezoidal shape. As moving away from the base 25 of the first electronic component 16, the cross section of the solder bump 61 decreases. The solder bump 61 melts at about 220° C. as the first solder balls 27. A distance between the second electrodes 26 and the tip of the solder bump 61 is, for example, 100 μm or less.

The reinforcing member 30 is preliminarily attached to the first electronic component 16 of the seventh embodiment. In the seventh embodiment, the reinforcing material 33 is attached to the first surface 38 of the supporting member 32. The fixing material 34 is attached to the second surface 39.

The reinforcing material 33 is interposed between the supporting member 32 and the base 25 of the first electronic component 16. Furthermore, the reinforcing material 33 covers each of the solder bumps 61 and is attached to the base 25 of the first electronic component 16.

As shown in FIG. 12, when the above-mentioned first electronic component 16 is mounted on the substrate 13, the reinforcing material 33 covering each solder bump 61 is liquefied and adhered to the solder bumps 61, the first electrodes 22, and the substrate 13. Furthermore, if there is a gap between the reinforcing material 33, solder bumps 61, and the base 25 of the first electronic component 16, the liquefied reinforcing material 33 is adhered to the solder bumps 61 and the base 25 to fill the gap.

Moreover, by the liquefying and thermally-cured reinforcing material 33, the supporting member 32 is fastened to the base 25 of the first electronic component 16. Furthermore, by the liquefying and thermally-cured fixing material 34, the supporting member 32 is fastened to the mounted surface 21 of the substrate 13.

In the TV 10 having the above-mentioned structure, the reinforcing material 33 covers the solder bumps 61 and is attached to the base 25 of the first electronic component 16. Since the solder bump 61 is arcuate, when reinforcing material 33 covers the solder bumps 61, occurrence of a gap between the reinforcing material 33, solder bumps 61, and base 25 is reduced. In other words, since the solder bump 61 is arcuate, the reinforcing material 33 easily contacts the base 25 and the solder bumps 61 without creating unnecessary gaps.

As a comparison, a case where the reinforcing material 33 covers the first solder balls 27 such as that of the first embodiment. Since the first solder balls 27 are spherical, a relatively large gap will easily be created between the reinforcing material 33 and the upper half of first solder balls 27. Contacting the reinforcing material 33 with the upper half of the first solder balls 27 tightly is difficult.

As explained above, with the second electrodes 26 comprising solder bumps 61, a possibility of creating a dead space between the reinforcing material 33 and the first electronic component 16 is reduced. Thereby, the contacting area of the reinforcing material 33 and the first electronic component 16 is increased, and the contacting parts of the first electrodes 22 and the solder bumps 61 are reinforced firmly.

The reinforcing material 33 is attached to the first surface 38 of the supporting member 32 and interposed between the base 25 of the first electronic component 16 and the supporting member 32. Thereby, comparing to the case where the reinforcing material 33 is attached to the second surface 39, a possibility that the reinforcing material 33 is torn apart by contacting something is reduced.

Furthermore, when the solder bumps 61 are provided with the second electrode 26 instead of the first solder balls 27, a distance between the base 25 of the first electronic component 16 and the substrate 13 becomes closer. Thereby, a possibility that the contacting parts of the first electrodes 22 and the solder bumps 61 are damaged is reduced.

Since the distance between the base 25 and the substrate 13 is narrow, supplying underfill resin between the base 25 and the substrate 13 may be difficult. However, the reinforcing member 30 reinforces the contacting parts of the first electrodes 22 and the solder bumps 61, the underfill resin itself is unnecessary. Furthermore, when the distance between the base 25 and the substrate 13 is narrow, the contacting parts of the first electrodes 22 and the solder bumps 61 may be reinforced only by the reinforcing material 33 excluding the supporting member 32 and the fixing material 34.

Next, the eighth embodiment is explained referring to FIG. 13. FIG. 13 is an exemplary cross-sectional view showing a part of the substrate 13 and the first electronic component 16 according to the eighth embodiment. As shown in FIG. 13, the reinforcing material 33 covers only a part of the first solder balls 27.

Even in the TV 10 having such a structure, the reinforcing material 33 with liquefaction and thermally-curing processes removes an oxide film on the first electrodes 22 and is fastened to the first solder balls 27 and the substrate 13. Thereby, the usage of the reinforcing material 33 is reduced and the production cost of the TV 10 is reduced as well.

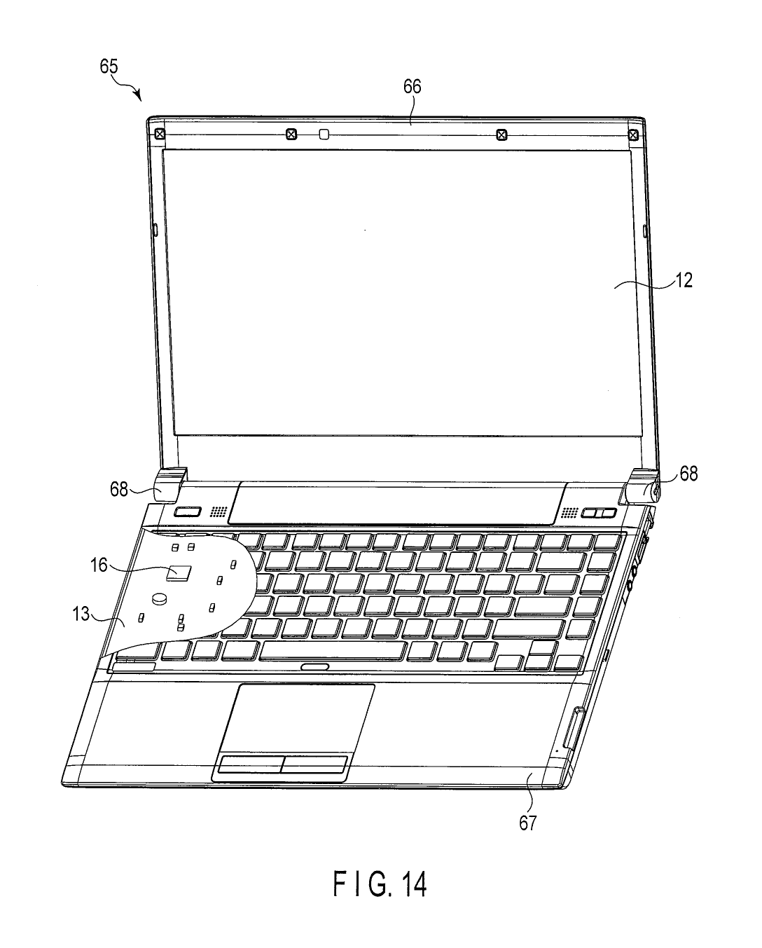

Next, the ninth embodiment is explained referring to FIG. 14. FIG. 14 is an exemplary perspective view showing a portable computer 65 of the ninth embodiment, and a part of the portable computer 65 is notched therein. The portable computer 65 is an example of an electronic apparatus.

As sown in FIG. 14, the portable computer 65 comprises a first casing 66 and a second casing 67. The second casing 67 is an example of a casing. A pair of hinges 68 are provided with end of the first casing 66. The second casing 67 is rotatably connected to the first casing 66 with the hinges 68.

The display part 12 is accommodated in the first casing 66. The substrate 13 is accommodated in the second casing 67. As in the first embodiment, the first electronic component 16 is mounted on the substrate 13. As shown in FIG. 2 to FIG. 4, the contacting parts of the first electrodes 22 and the first solder balls 27 are reinforced by the reinforcing member 30.

The electronic apparatus is not limited to the TV 10 of the first to eighth embodiments, and may be other electronic apparatuses such as a portable computer 65, tablet computer, cellular phone, etc.

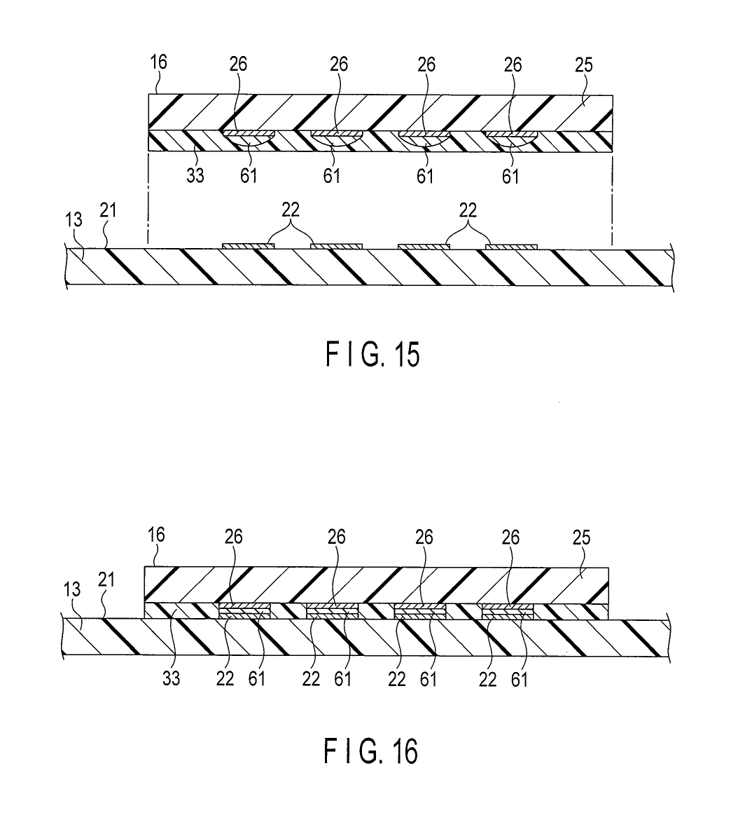

Next, the tenth embodiment is explained referring to FIGS. 15 and 16. FIG. 15 is an exemplary cross-sectional view showing a part of the substrate 13 and the first electronic component 16 according to the tenth embodiment in a disassembled fashion. FIG. 16 is an exemplary cross-sectional view showing a part of the substrate 13 and the first electronic component 16 mounted thereon.

As shown in FIG. 15, the first electronic component 16 of the tenth embodiment comprises a plurality of solder bumps 61 as in the seventh embodiment. The solder bumps 61 are provided with the second electrodes 26, respectively. Each of he solder bumps 61 is formed in an arcuate shape, and its cross section decreases as moving away from the base 25 of the first electronic component 16. Here, the shape of the solder bumps 61 may be trapezoidal and conical.

The reinforcing material 33 is preliminarily attached to the first electronic component 16. The reinforcing material 33 is a film formed of thermosetting resin configured to remove an oxide film. The thickness of the reinforcing material 33 is, for example, 100 μm or more. In other words, the thickness of the reinforcing material 33 is thicker than the distance between the base 25 of the first electronic component 16 and the tips of the solder bumps 61.

When the reinforcing material 33 is liquefied and cooled, the reinforcing material 33 is attached to the base 25 of the first electronic component 16 and covers the solder bumps 61. In other words, the solder bumps 61 are embedded in the reinforcing material 33. Here, the reinforcing material 33 is not limited to the above-mentioned use, and may be attached only to the tips of the solder bumps 61 without attaching to the base 25, for example.

For example, the first electronic component 16 is mounted on the substrate 13 as follows. Firstly, the first electronic component 16 is placed on the mounted surface 21 of the substrate 13 so that the first electronic component 16 covers the first electrodes 22. Thereby, the reinforcing material 33 covering the solder bumps 61 contacts the first electrodes 22. The reinforcing material 33 is interposed between the solder bumps 61 and the first electrodes 22 and also interposed between the substrate 13 and the base 25 of the first electronic component 16.

Next, the first electronic component 16 is heated and pressed against the substrate 13. The heated reinforcing material 33 liquefies and pushed out from the interval between the solder bumps 61 and the first electrodes 22. At the same time, the reinforcing material 33 removes an oxide film on the first electrodes 22. Thereby, the solder bumps 61 contact the first electrodes 22.

When the first electronic component 16 is further heated, the reinforcing material 33 is thermally-cured. Thereby, the reinforcing material 33 is fastened to the base 25 of the first electronic component 16, substrate 13, and solder bumps 61. The first electronic component 16 is fixed to the substrate 13 by the reinforcing material 33. As described above, the reinforcing material 33 is fastened to the substrate 13 and the solder bumps 61, and fixes the base 25 to the substrate 13 to reinforce the contacting parts of the solder bumps 61 and the first electrodes 22.

In the TV 10 having the above-mentioned structure, the contacting parts of the solder bumps 61 and the first electrodes 22 is reinforced only by the reinforcing material 33. Thereby, parts and cost for producing the TV 10 can be reduced.

The cross section of the solder bump 61 becomes smaller as moving away from the base 25 of the first electronic component 16. Thereby, when the reinforcing material 33 is attached to the first electronic component 16 to adhere to the base 25, occurrence of bubbles between the reinforcing material 33 and the solder bumps 61 can be suppressed. For example, when the first solder balls 27 of the first embodiment are used instead of the solder bumps 61, bubbles will remain at a narrowed portion of the first solder balls 27. In contrast, when the solder bumps 61 are used, occurrence of bubbles is suppressed, and the reinforcing material 33 firmly adhered to the solder bumps 61. Thereby, the contacting parts of the solder bumps 61 and the first electrodes 22 can be reinforced firmly.

According to one or more television receiving apparatus, electronic component, and electronic apparatus described above, a reinforcing material is configured to remove an oxide film and firmly fixed to solders and substrate. Thus, both oxide film removal and reinforcement are performed in a single process. Thereby, the production cost is reduced.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

For example, in the third to sixth embodiment, the reinforcing member 30 may be attached to the first electronic component 16 in advance. Furthermore, in the first to sixth embodiments, the reinforcing material 33 may be attached to the first surface 38 of the supporting member 32 and the fixing material 34 may be attached to the second surface 39. That is, various embodiments may be combined. In addition, the supporting member 32 is not limited to a framed-shape and may be formed, for example, as a plurality of plates each of which corresponds to the outer peripheral 25a of the base 25 of the first electronic component 16.

What is claimed is:

1. An electronic apparatus comprising:
a substrate comprising a plurality of first electrodes;
a first electronic component comprising a base, a plurality of second electrodes on the base, and a plurality of first solders configured to electrically connect the first electrodes to the second electrodes; and
a reinforcing member comprising a supporting member at least partially interposed between the substrate and the base of the first electronic component and a reinforcing material fixed to the supporting member, the reinforcing member fixed to the substrate and the base, and the reinforcing material formed of a first thermosetting resin configured to remove an oxide film and fastened to the first solders and the substrate.

2. The electronic apparatus of claim 1, wherein
the supporting member is fixed to either one of the substrate or the base of the first electronic component by the reinforcing material, and fixed to the other one of the substrate or the base by a second thermosetting resin.

3. The electronic apparatus of claim 2, wherein
the supporting member is configured to surround the first and second electrodes, and
the reinforcing material is over a region surrounded by the supporting member.

4. The electronic apparatus of claim 3, further comprising a second electronic component comprising a bottom, a plurality of third electrodes on the bottom, and a plurality of second solders, wherein
the substrate further comprises a plurality of fourth electrodes electrically connected to the third electrodes by the second solders,
the supporting member of the reinforcing member is configured to surround the third electrodes and the fourth electrodes and fixed to the second electronic component, and
the reinforcing material is fastened to the second solders and the substrate.

5. The electronic apparatus of claim 2, wherein the supporting member comprises a plurality of openings configured to store the first solders.

6. The electronic apparatus of claim 2, further comprising a thermosetting reinforcing resin between the substrate and the base of the first electronic component, fastened to the base, and fastened to the reinforcing material fastening to the substrate, wherein
a gap configured to receive the reinforcing resin in a pre-thermally-cured fashion is defined between an outer periphery of the base of the first electronic component and a part of the supporting member.

7. The electronic apparatus of claim 4, further comprising a thermosetting reinforcing resin between the substrate and the base of the first electronic component, fastened to the base, and fastened to the reinforcing material fastening to the substrate, wherein
a gap configured to receive the reinforcing resin in a pre-thermally-cured fashion is defined between an outer periphery of the base of the first electronic component and a part of the supporting member.

8. The electronic apparatus of claim 2, wherein
the base of the first electronic component comprises a projection toward the substrate, and
the supporting member is open frame shaped configured to allow the projection of the base to pass through.

9. The electronic apparatus of claim 7, wherein
the base of the first electronic component comprises a projection toward the substrate, and
the supporting member is open frame shaped configured to allow the projection of the base to pass through.

10. The electronic apparatus of claim 2, wherein
the first solders of the first electronic component comprise a plurality of bumps on the second electrodes, and
the reinforcing material covers at least a part of the first solders and is attached to the base of the first electronic component.

11. The electronic apparatus of claim 3, wherein
the first solders of the first electronic component comprise a plurality of bumps on the second electrodes, and
the reinforcing material covers at least a part of the first solders and is attached to the base of the first electronic component.

12. The electronic apparatus of claim 2, wherein the reinforcing material is thermoplastic before being thermally-cured, liquefied when being heated, and thermally-cured when being further heated, and a liquefaction temperature of the reinforcing material is lower than a melting temperature of the first solders.

13. The electronic apparatus of claim 9, wherein the reinforcing material is thermoplastic before being thermally-cured, liquefied when being heated, and thermally-cured when being further heated, and a liquefaction temperature of the reinforcing material is lower than a melting temperature of the first solders.

14. An electronic component comprising:
a base comprising a plurality of electrodes;
a plurality of solders on the electrodes;
a supporting member at least a part of which is fixed to the base; and
a reinforcing material formed of a thermosetting resin configured to remove an oxide film, the reinforcing material attached to the supporting member configured to cover at least a part of the solders.

15. The electronic component of claim 14, wherein
the supporting member comprises a first surface fixed to the base and a second surface opposite to the first surface, and
the reinforcing material is attached to the second surface of the supporting member configured to cover at least a part of the solders.

16. The electronic component of claim 14, wherein
the supporting member comprises a first surface fixed to the base and a second surface opposite to the first surface, and
the reinforcing material is attached to the first surface of the supporting member configured to cover at least a part of the solders.

17. An electronic component comprising:
a base comprising a plurality of electrodes;
a plurality of solders on the electrodes, each of the solders having a cross-sectional area which decreases as moving away from the base; and
a reinforcing material formed of a thermosetting resin configured to remove an oxide film and covering at least a part of the solders.
